(19) United States
(12) Patent Application Publication
(10) Pub. No.: US 2024/0401258 A1
(43) Pub. Date: Dec. 5, 2024

(54) ELECTRONIC APPARATUS FOR PREVENTING POWER FAILURE AND CONTROLLING METHOD THEREOF

(71) Applicant: Samsung Electronics Co., Ltd., Suwon-si (KR)

(72) Inventors: Sukwoo PARK, Suwon-si (KR); Sangyeol LEE, Suwon-si (KR); Jaepoong LEE, Suwon-si (KR)

(21) Appl. No.: 18/633,995

(22) Filed: Apr. 12, 2024

Related U.S. Application Data
(63) Continuation of application No. PCT/KR2024/003055, filed on Mar. 8, 2024.

(30) Foreign Application Priority Data
Jun. 1, 2023 (KR) 10-2023-0070981

(51) Int. Cl. D06F 34/10; D06F 33/32; D06F 34/04; D06F 34/14; D06F 34/28; D06F 58/36; D06F 103/44; D06F 105/50; D06F 105/52; D06F 105/58; D06F 105/62

(52) U.S. Cl. CPC D06F 34/10; D06F 33/32; D06F 34/04; D06F 34/14; D06F 34/28; D06F 58/36; D06F 2103/44; D06F 2105/50; D06F 2105/52; D06F 2105/58; D06F 2105/62

(57) ABSTRACT

An electronic apparatus is provided. The electronic apparatus includes a communication interface, memory storing one or more computer programs, and one or more processors communicatively connected to the communication interface and the memory, wherein the one or more computer programs include computer-executable instructions that, when executed by the one or more processors, cause the electronic apparatus to receive operation information of another electronic apparatus through the communication interface, identify a power consumption of the electronic apparatus and the other electronic apparatus based on the operation information of the electronic apparatus and the operation information of the other electronic apparatus, and based on the identified power consumption being equal to or greater than threshold power, change at least one of an operation of the electronic apparatus or an operation of the other electronic apparatus so that the identified power consumption is less than the threshold power.

### CROSS-REFERENCE TO RELATED APPLICATION(S)

This application is a continuation application, claiming priority under § 365 (c), of an International application No. PCT/KR2024/003055, filed on Mar. 8, 2024, which is based on and claims the benefit of a Korean patent application number 10-2023-0070981, filed on Jun. 1, 2023, in the Korean Intellectual Property Office, the disclosure of which is incorporated by reference herein in its entirety.

### FIELD

The disclosure relates to an electronic apparatus and a controlling method thereof. More particularly, the disclosure relates to an electronic apparatus that prevents power failure and a controlling method thereof.

### DESCRIPTION OF THE RELATED ART

With the development of electronic technology, electronic apparatuses that provide various functions are being developed. In particular, home appliances can frequently store information necessary for operation in non-volatile memory, and information stored in the non-volatile memory is not lost even when power is cut off.

Home appliances can perform operations based on information stored in non-volatile memory. Accordingly, when power is supplied again after power is cut off, the home appliances can continuously perform the previous operations.

Recently, home appliances such as washing machines and dryers are stacked as an integrated unit, and when the washing machines and dryers operate at full power, power to the washing machines and dryers may be cut off due to excessive power use.

In this case, the washing machines and dryers store the previous state and thus, can continuously perform the previous operations when power is supplied again. However, the power may be cut off again for the same reason. Accordingly, a method to solve this problem needs to be developed.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic apparatus that prevents power failure and a controlling method thereof.

Additional aspects will be set forth in part in the description which follows and, in part, will be apparent from the description, or may be learned by practice of the presented embodiments.

In accordance with an aspect of the disclosure, an electronic apparatus is provided. The electronic apparatus includes a communication interface, memory storing one or more computer programs, and one or more processors communicatively connected to the communication interface and the memory, wherein the one or more computer programs include computer-executable instructions that, when executed by the one or more processors, cause the electronic apparatus to receive operation information of another electronic apparatus through the communication interface, identify a power consumption of the electronic apparatus and another electronic apparatus based on the operation information of the electronic apparatus and the operation information of another electronic apparatus, and, based on the identified power consumption being equal to or greater than threshold power, change at least one of an operation of the electronic apparatus or an operation of another electronic apparatus so that the identified power consumption is less than the threshold power.

The one or more computer programs further include computer-executable instructions that, when executed by the one or more processors, cause the electronic apparatus to, based on the identified power consumption being equal to or greater than the threshold power, perform at least one of delaying at least one of an operation of the electronic apparatus or an operation of another electronic apparatus, changing an order of a subordinate operation or changing control output.

The one or more computer programs further include computer-executable instructions that, when executed by the one or more processors, cause the electronic apparatus to identify a plurality of power consumptions corresponding to each of a plurality of time periods based on the operation information of the electronic apparatus and the operation information of another electronic apparatus, and based on identifying the power consumption to be equal to or greater than the threshold power, change at least one of an operation of the electronic apparatus or an operation of another electronic apparatus of a time period corresponding to the identified power consumption.

The electronic apparatus further includes a user interface, and the one or more computer programs further include computer-executable instructions that, when executed by the one or more processors, cause the electronic apparatus to, based on a control command for changing an operation of the electronic apparatus being received through the user interface, re-identify a power consumption of the electronic apparatus and another electronic apparatus based on operation information of the electronic apparatus and operation information of another electronic apparatus corresponding to the control command.

The one or more computer programs further include computer-executable instructions that, when executed by the one or more processors, cause the electronic apparatus to, based on the identified power consumption being equal to or greater than the threshold power, control the communication interface to transmit a message indicating a possible power cut-off to a user terminal, and based on a user command being received from the user terminal through the communication interface, change at least one of an operation of the electronic apparatus or an operation of another electronic apparatus based on the user command.

The one or more computer programs further include computer-executable instructions that, when executed by the one or more processors, cause the electronic apparatus to store an operation history of the electronic apparatus and another electronic apparatus in the memory at predetermined time interval, based on a power being supplied again after the power is cut-off while the electronic apparatus is in operation and thus, the operation is stopped, identify the power cut-off as it is identified that the operation history and a current operation of the electronic apparatus do not match, and store a power consumption of the electronic apparatus and a power consumption of another electronic apparatus at a time of the power cut-off in the memory.

The one or more computer programs further include computer-executable instructions that, when executed by the one or more processors, cause the electronic apparatus to identify a sum of the power consumption of the electronic apparatus and the power consumption of another electronic apparatus at the time of the power cut-off as the threshold power.

The one or more computer programs further include computer-executable instructions that, when executed by the one or more processors, cause the electronic apparatus to, based on a plurality of power cut-off histories being stored in the memory, identify a lowest value from the sum of the power consumption of the electronic apparatus and the power consumption of another electronic apparatus in each of the plurality of power cut-off histories as the threshold power.

The electronic apparatus and another electronic apparatus receive power from a same power source.

In an embodiment, the electronic apparatus is a dryer, the other electronic apparatus is a washing machine. In this embodiment, the one or more computer programs further include computer-executable instructions that, when executed by the one or more processors, cause the electronic apparatus to, based on the identified power consumption being equal to or greater than the threshold power, control the communication interface to transmit a control signal for changing at least one of operations of another electronic apparatus to another electronic apparatus

In accordance with another aspect of the disclosure, a method of controlling an electronic apparatus is provided. The method includes receiving, by the electronic apparatus, operation information of another electronic apparatus, identifying, by the electronic apparatus, a power consumption of the electronic apparatus and another electronic apparatus based on the operation information of the electronic apparatus and the operation information of another electronic apparatus, and based on the identified power consumption being equal to or greater than threshold power, changing, by the electronic apparatus, at least one of an operation of the electronic apparatus or an operation of another electronic apparatus so that the identified power consumption is less than the threshold power.

The changing of the at least one of an operation of the electronic apparatus or the operation of the other electronic apparatus includes, based on the identified power consumption being equal to or greater than the threshold power, performing at least one of delaying at least one of an operation of the electronic apparatus or an operation of another electronic apparatus, changing an order of a subordinate operation or changing control output.

The identifying of the power consumption of the electronic apparatus and the other electronic apparatus includes identifying a plurality of power consumptions corresponding to each of a plurality of time periods based on the operation information of the electronic apparatus and the operation information of another electronic apparatus, and the changing of the at least one of an operation of the electronic apparatus or the operation of the other electronic apparatus includes, based on identifying the power consumption to be equal to or greater than the threshold power, changing at least one of an operation of the electronic apparatus or an operation of another electronic apparatus of a time period corresponding to the identified power consumption.

The method further includes, based on a control command for changing an operation of the electronic apparatus being received, re-identifying a power consumption of the electronic apparatus and another electronic apparatus based on operation information of the electronic apparatus and operation information of another electronic apparatus corresponding to the control command.

The changing includes, based on the identified power consumption being equal to or greater than the threshold power, transmitting a message indicating a possible power cut-off to a user terminal, and based on a user command being received from the user terminal, changing at least one of an operation of the electronic apparatus or an operation of another electronic apparatus based on the user command.

The method includes storing an operation history of the electronic apparatus and another electronic apparatus in the memory at predetermined time interval, based on a power being supplied again after the power is cut off while the electronic apparatus is in operation and thus, the operation is stopped, identifying the power cut-off as it is identified that the operation history and a current operation of the electronic apparatus do not match, and storing a power consumption of the electronic apparatus and a power consumption of another electronic apparatus at a time of the power cut-off in the memory.

The method further includes identifying a sum of the power consumption of the electronic apparatus and the power consumption of another electronic apparatus at the time of the power cut-off as the threshold power.

The identifying includes, based on a plurality of power cut-off histories being stored in the memory, identify a lowest value from the sum of the power consumption of the electronic apparatus and the power consumption of another electronic apparatus in each of the plurality of power cut-off histories as the threshold power.

In accordance with another aspect of the disclosure, one or more non-transitory computer-readable storage media storing one or more computer programs including computer-executable instructions that, when executed by one or more processors of an electronic apparatus, cause the electronic apparatus to perform operations are provided. The operations include receiving, by the electronic apparatus, operation information of another electronic apparatus, identifying, by the electronic apparatus, a power consumption of the electronic apparatus and the other electronic apparatus based on operation information of the electronic apparatus and the operation information of the other electronic apparatus, and based on the identified power consumption being equal to or greater than threshold power, changing, by the electronic apparatus, at least one of an operation of the electronic apparatus or an operation of the other electronic apparatus so that the identified power consumption is less than the threshold power.

The electronic apparatus and the other electronic apparatus receive power from a same power source.

In an embodiment, the electronic apparatus is a dryer, the other electronic apparatus is a washing machine, and the changing includes, based on the identified power consumption being equal to or greater than the threshold power, transmitting a control signal for changing at least one of operations of another electronic apparatus to another electronic apparatus.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating configuration of an electronic system according to an embodiment of the disclosure;

FIG. 2 is a block diagram illustrating configuration of an electronic apparatus according to an embodiment of the disclosure;

FIG. 3 is a block diagram illustrating detailed configuration of an electronic apparatus according to an embodiment of the disclosure;

FIGS. 4 and 5 are views provided to explain power consumed for each operation according to various embodiments of the disclosure;

FIGS. 6 and 7 are views provided to explain a case where a power consumption is equal to or greater than threshold power according to various embodiments of the disclosure;

FIGS. 8, 9, and 10 are views provided to explain an operation method in a case where a power consumption is equal to or greater than threshold power according to various embodiments of the disclosure;

FIG. 11 is a flowchart provided to explain a method of calculating threshold power according to an embodiment of the disclosure;

FIG. 12 is a flowchart provided to explain a power cut-off avoidance operation according to an embodiment of the disclosure; and

FIG. 13 is a flowchart provided to explain a controlling method of an electronic apparatus according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

The disclosure is to provide an electronic apparatus that stores power cut-off conditions of an electronic apparatus and other electronic apparatuses and prevents reoccurrence of power cut-off and a controlling method thereof.

Hereinafter, the disclosure is described in detail with reference to the accompanying drawings.

General terms that are currently widely used are selected as the terms used in embodiments of the disclosure in consideration of their functions in the disclosure, and may be changed based on the intention of those skilled in the art or a judicial precedent, the emergence of a new technique, or the like. In addition, in a specific case, terms arbitrarily chosen by an applicant may exist. In this case, the meanings of such terms are mentioned in detail in corresponding descriptions of the disclosure. Therefore, the terms used in the embodiments of the disclosure need to be defined on the basis of the meanings of the terms and the contents throughout the disclosure rather than simple names of the terms.

In the disclosure, an expression “have”, “may have”, “include”, “may include” or the like, indicates the existence of a corresponding feature (e.g., a numerical value, a function, an operation or a component such as a part), and does not exclude the existence of an additional feature.

In the disclosure, an expression “have”, “may have”, “include”, “may include” or the like, indicates the existence of a corresponding feature (e.g., a numerical value, a function, an operation or a component such as a part), and does not exclude the existence of an additional feature.

An expression, “at least one of A or/and B” may indicate either “A or B”, or “both of A and B.”

Expressions “first”, “second”, and the like, used in the disclosure may indicate various components regardless of the sequence or importance of the components. These expressions are used only to distinguish one component from another component, and do not limit the corresponding components.

A term of a singular number may include its plural number unless explicitly indicated otherwise in the context. It is to be understood that a term “include”, “formed of”, or the like used in the application specifies the presence of features, numerals, steps, operations, components, parts, or combinations thereof, mentioned in the specification, and does not preclude the presence or addition of one or more other features, numerals, steps, operations, components, parts, or combinations thereof.

In the disclosure, the term ‘user’ may refer to a person using an electronic apparatus or a device using an electronic apparatus (e.g., an artificial intelligence electronic apparatus).

Hereinafter, various embodiments will be described in greater detail with reference to the accompanying drawings.

It should be appreciated that the blocks in each flowchart and combinations of the flowcharts may be performed by one or more computer programs which include instructions. The entirety of the one or more computer programs may be stored in a single memory or the one or more computer programs may be divided with different portions stored in different multiple memories.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an integrated circuit (IC), or the like.

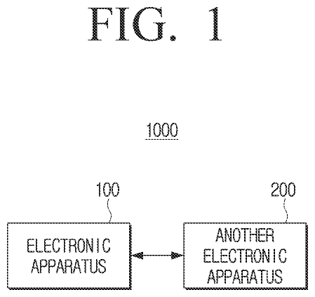

FIG. 1 is a block diagram illustrating configuration of an electronic system according to an embodiment of the disclosure.

Referring to FIG. 1, an electronic system 1000 includes an electronic apparatus 100 and another electronic apparatus 200. For example, the electronic system 1000 includes a dryer as the electronic apparatus 100 and a washing machine as another electronic apparatus 200.

The electronic apparatus 100 may be an apparatus that receives operation information of another electronic apparatus 200, identifies a power consumption of the electronic apparatus 100 and another electronic apparatus 200 based on the operation information of the electronic apparatus 100 and the operation information of another electronic apparatus 200, and if the identified power consumption is equal to or greater than threshold power, changes at least one of the operation of the electronic apparatus 100 or the operation of another electronic apparatus so that the identified power consumption is less than the threshold power.

In other words, the electronic apparatus 100 may be an apparatus that identifies power consumed simultaneously by the electronic apparatus 100 and another electronic apparatus 200, and changes at least one of the operation of the electronic apparatus 100 or the operation of another electronic apparatus 200 in order to prevent the problem of power cut-off for the electronic apparatus 100 and another electronic apparatus 200 as the power consumption is equal to or greater than the threshold power.

Another electronic apparatus 200 is one of the apparatuses that operates simultaneously with the electronic apparatus 100, and may be an apparatus that provides the operating state of another electronic apparatus 200 to the electronic apparatus 100. For example, when a user command is received, another electronic apparatus 200 transmits operation information corresponding to the user command to the electronic apparatus 100. Alternatively, when a request for operation information is received from the electronic apparatus 100, another electronic apparatus 200 may transmit the operation information of another electronic apparatus 200 to the electronic apparatus 100.

Meanwhile, the electronic apparatus 100 may directly perform communication with another electronic apparatus 200. Alternatively, the electronic apparatus 100 may perform communication with another electronic apparatus 200 through a server.

Referring to FIG. 1, for convenience of description, only the electronic apparatus 100 and another electronic apparatus 200 are illustrated, but the disclosure is not limited thereto. For example, the electronic apparatus 100 changes at least one of an operation of the electronic apparatus 100 or an operation of a plurality of electronic apparatuses based on a power consumption of the electronic apparatus 100 and the plurality of other electronic apparatuses.

Alternatively, the electronic apparatus 100 and another electronic apparatus 200 may be home appliances other than a dryer and a washing machine, respectively.

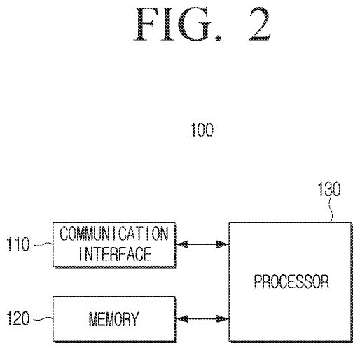

FIG. 2 is a block diagram illustrating configuration of an electronic apparatus according to an embodiment of the disclosure.

Referring to FIG. 2, the electronic apparatus 100 includes a communication interface 110, memory 120 and a processor 130.

The communication interface 110 is configured to perform communication with various types of externa devices according to various types of communication methods. For example, the electronic apparatus 100 performs communication with another electronic apparatus 200, a server or a user terminal through the communication interface 110.

The communication interface 110 may include a wireless fidelity (Wi-Fi) module, a Bluetooth module, an infrared communication module, a wireless communication module, and the like. Each communication module may be implemented in the form of at least one hardware chip.

The Wi-Fi module and the Bluetooth module perform communication using a Wi-Fi method and a Bluetooth method, respectively. When using a Wi-Fi module or a Bluetooth module, various connection information such as service set identifier (SSID) and session key are first transmitted and received, and various information can be transmitted and received after establishing communication connection using this. The infrared communication module performs communication according to an infrared Data Association (IrDA) communication technology which transmits data wirelessly over a short distance using infrared rays between optical light and millimeter waves.

In addition to the above-described communication methods, the wireless communication module includes at least one communication chip that performs communication according to various wireless communication standards, such as zigbee, 3^{rd} Generation (3G), 3^{rd} Generation Partnership Project (3GPP), Long Term Evolution (LTE), LTE advanced (LTE-A), 4^{th} Generation (4G), 5^{th} Generation (5G), and the like.

Alternatively, the communication interface 110 may include a wired communication interface such as high definition multimedia interface (HDMI), display port (DP), Thunderbolt, USB, red green blue (RGB), D-subminiature (D-SUB), digital visual interface (DVI), and the like.

In addition, the communication interface 110 may include at least one of a Local Area Network (LAN) module, an Ethernet module or a wired communication module that performs communication using a pair cable, a coaxial cable or an optical fiber cable.

The memory 120 may refer to hardware that stores information such as data in electrical or magnetic form so that the processor 130 or the like can access the information. To this end, the memory 120 may be implemented as at least one hardware among non-volatile memory, volatile memory, flash memory, hard disk drive (HDD) or Solid State Drive (SSD), random access memory (RAM), read only memory (ROM) or the like.

The memory 120 may store at least one instruction required for the operation of the electronic apparatus 100 or the processor 130. The instruction is a code unit that instructs the operation of the electronic apparatus 100 or the processor 130, and may be written in a machine language that may be understood by a computer. Alternatively, the memory 120 may store a plurality of instructions as a set of instructions that perform a specific task of the electronic apparatus 100 or the processor 130.

The memory 120 may store data, which is information in bits or bytes that can represent letters, numbers, images, and the like. For example, the memory 120 stores operation information, power cut-off history, and the like. The operation information may include operation information of the electronic apparatus 100, operation information of another electronic apparatus 200, and the like. For example, the operation information includes a first operation of the electronic apparatus 100 and a second operation of another electronic apparatus 200. Alternatively, the operation information may include a power consumption of the first operation of the electronic apparatus 100 and a power consumption of the second operation of another electronic apparatus 200. In addition, the power cut-off history may include a history of power cut-off for the electronic apparatus 100, such as a short circuit, and information regarding a power consumption of the electronic apparatus 100 and another electronic apparatus 200 at the time of power cut-off.

The memory 120 is accessed by the processor 130, and reading/recording/modifying/deleting/updating for instructions, a set of instructions or data may be performed by the processor 130.

The processor 130 controls the overall operations of the electronic apparatus 100. Specifically, the processor 130 is connected to each component of the electronic apparatus 100 and may control the overall operations of the electronic apparatus 100. For example, the processor 130 is connected to components such as the communication interface 110, the memory 120 and a user interface (not illustrated) and controls the operations of the electronic apparatus 100.

At least one processor 130 may include one or more or a CPU, a Graphics Processing Unit (GPU), an Accelerated Processing Unit (APU), a Many Integrated Core (MIC), a Neural Processing Unit (NPU), a hardware accelerator, or a machine learning accelerator. At least one processor 130 may control one or any combination of other components of the electronic apparatus 100, and may perform a communication-related operation or data processing. At least one processor 130 may execute one or more programs or instructions stored in the memory 120. For example, at least one processor 130 performs a method according to an embodiment by executing one or more instructions stored in the memory 120.

When the method according to an embodiment includes a plurality of operations, the plurality of operations may be performed by one processor or by a plurality of processors. For example, when the first operation, the second operation and the third operation are performed by the method according to an embodiment, all of the first operation, the second operation and the third operation are performed by the first processor, or the first operation and the second operation is performed by the first processor (e.g., a general-purpose processor) and the third operation is performed by the second processor (e.g., an artificial intelligence (AI)-only processor).

At least one processor 130 may be implemented as a single core processor including one core or one or more multi-core processors including a plurality of cores (e.g., homogeneous multi-core or heterogeneous multi-core). When at least one processor 130 is implemented as a multi-core processor, each of the plurality of cores included in the multi-core processor may include internal memory such as cache memory and on-chip memory, and a common cache shared by the plurality of cores may be included in the multi-core processor. In addition, each of the plurality of cores (or some of the plurality of cores) included in the multi-core processor may independently read and perform program instructions for implementing the method according to an embodiment, and all of the plurality of cores (or some of them) may be linked to read and perform program instructions for implementing the method according to an embodiment.

When the method according to an embodiment includes a plurality of operations, the plurality of operations may be performed by one core among the plurality of cores included in the multi-core processor, or may be performed by a plurality of cores. For example, when the first operation, the second operation and the third operation are performed by the method according to an embodiment, all of the first operation, the second operation and the third operation are performed by the first core included in the multi-core processor, or the first operation and the second operation is performed by the first core and the third operation is performed by the second core included in the multi-core processor.

In embodiments of the disclosure, at least one processor 130 may be a system-on-chip (SoC) where one or more processors and other electronic components are integrated, a single-core processor, a multi-core processor, or a core included in the single-core processor or the multi-core processor. The core may be implemented as CPU, GPU, APU, MIC, NPU, hardware accelerator, machine learning accelerator, or the like, but is not limited thereto. However, hereinafter, for convenience of explanation, the operation of the electronic apparatus 100 will be described using the term, ‘processor 130’.

The processor 130 may receive operation information of another electronic apparatus 200 through the communication interface 110. For example, when the operation of the electronic apparatus 100 is performed according to a user command, operation information of another electronic apparatus 200 is requested from another electronic apparatus 200, and the operation information of another electronic apparatus 200 is received from another electronic apparatus 200. Alternatively, the processor 130 may receive the operation information of another electronic apparatus 200 from another electronic apparatus 200 even if the operation information of another electronic apparatus 200 is not requested from another electronic apparatus 200. For example, when a user command is received, another electronic apparatus 200 transmits operation information corresponding to the user command to the electronic apparatus 100.

The electronic apparatus 100 and another electronic apparatus 200 may receive power from the same power source. For example, the electronic apparatus 100 and another electronic apparatus 200 are supplied with power through one of a plurality of power lines arranged in one residential space. However, the disclosure is not limited thereto, and the disclosure is applied to any case in which as the electronic apparatus 100 and another electronic apparatus 200 are used simultaneously, there is a risk of exceeding the power supply limit. For example, each of the electronic apparatus 100 and another electronic apparatus 200 are connected to a first power line and a second power line from among a plurality of power lines arranged in one residential space, but as the two apparatuses are used simultaneously, the power supply limit of the entire residential space may be exceeded. Even in this case, the electronic apparatus 100 and another electronic apparatus 200 of the disclosure can be applied.

The processor 130 may identify a power consumption of the electronic apparatus 100 and another electronic apparatus 200 based on operation information of the electronic apparatus 100 and operation information of another electronic apparatus 200. For example, the processor 130 identifies the power consumption of the electronic apparatus 100 and another electronic apparatus 200 as ‘100’ based on the first operation of the electronic apparatus 100 and the second operation of another electronic apparatus 200.

When the identified power consumption is equal to or greater than a threshold power, the processor 130 may change at least one of the operation of the electronic apparatus 100 or the operation of another electronic apparatus 200 so that the identified power consumption is less than the threshold power. For example, when the identified power consumption is 100 and the threshold power is 90, at least one of the operation of the electronic apparatus 100 or the operation of another electronic apparatus 200 is changed so that the threshold power becomes less than 90.

When the identified power consumption is equal to or greater than the threshold power, the processor 130 may perform at least one of delaying at least one of an operation of the electronic apparatus or an operation of another electronic apparatus, changing an order of a subordinate operation or changing control output. For example, when the identified power consumption is equal to or greater than the threshold power, the processor 130 temporarily stops the operation of the electronic apparatus 100, and when the power consumption of another electronic apparatus 200 decreases, the operation of the electronic apparatus 100 is resumed. Alternatively, when the identified power consumption is equal to or greater than the threshold power, the processor 130 may first perform a second operation that is a low priority instead of a first operation that is the current operation and then, resume the first operation. Alternatively, when the identified power consumption is equal to or greater than the threshold power, the processor 130 may lower the control output of the operation of the electronic apparatus 100 to maintain the total power consumption below the threshold power. However, the disclosure is not limited thereto. When the identified power consumption is equal to or greater than the threshold power, the processor 130 may change the operation of another electronic apparatus 200 or change both the operation of the electronic apparatus 100 and the operation of another electronic apparatus 200. For example, when the identified power consumption is equal to or greater than the threshold power, the processor 130 lowers the control output of the operation of the electronic apparatus 100, and lower the control output of the operation of another electronic apparatus 200 to maintain the total power consumption below the threshold power. When changing the operation of another electronic apparatus 200, the electronic apparatus 100 may transmit a control command including change information to another electronic apparatus 200.

The processor 130 may identify a plurality of power consumptions corresponding to a plurality of time periods based on operation information of the electronic apparatus 100 and operation information of another electronic apparatus 200, and when a power consumption equal to or greater than the threshold power is identified from among the plurality of power consumptions, may change at least one of the operation of the electronic apparatus 100 or the operation of another electronic apparatus 200 in the time period corresponding to the identified power consumption. For example, the operation information of the electronic apparatus 100 includes a first operation for 0 to 10 minutes, a second operation for 10 to 30 minutes, and a third operation for 30 to 40 minutes, and the operation information of another electronic apparatus 200 may include a fourth operation for 0 to 10 minutes, a fifth operation for 10 to 20 minutes, a sixth operation for 20 to 30 minutes, and a seventh operation for 30 to 40 minutes. In this case, the processor 130 may identify the total power consumption of the electronic apparatus 100 and another electronic apparatus 200 for 0 to 10 minutes, the total power consumption of the electronic apparatus 100 and another electronic apparatus 200 for 10 to 20 minutes, the total power consumption of the electronic apparatus 100 and another electronic apparatus 200 for 20 to 30 minutes, and the total power consumption of the electronic apparatus 100 and another electronic apparatus for 30 to 40 minutes, and identify whether each of the plurality of total power consumptions is equal to or greater than the threshold power. The processor 130 may maintain the total power consumption below the threshold power by adjusting the operation of the time period in which the total power consumption exceeds the threshold power.

The electronic apparatus 100 further includes a user interface, and when a control command for changing the operation of the electronic apparatus 100 is received through the user interface, the processor 130 may re-identify the power consumption of the electronic apparatus 100 and another electronic apparatus 200 based on the operation information of the electronic apparatus 100 and the operation information of another electronic apparatus 200 corresponding to the control command. In this case as well, the processor 130 may re-identify the power consumption for a plurality of time periods as described above.

When the identified power consumption is equal to or greater than the threshold power, the processor 130 may control the communication interface 110 to transmit a message indicating the possibility of power cut-off to a user terminal, and when a user command is received from the user terminal through the communication interface 110, the processor 130 may change at least one of the operation of the electronic apparatus 100 or the operation of another electronic apparatus 200 based on the user command. In this case, the processor 130 may provide a plurality of options to the user terminal. For example, the processor 130 provides options such as time priority or performance priority. The time priority may be a method of completing all operations as quickly as possible, and the performance priority may be a method of maintaining the continuity or sequentiality of the operation as much as possible.

The processor 130 may store the operation history of the electronic apparatus 100 and another electronic apparatus 200 in the memory 120 at predetermined time intervals, and when power is cut off during the operation of the electronic apparatus 100 and power is supplied again after the operation of the electronic apparatus 100 is stopped, the processor 130 may identify that the power is cut off as it is identified that the operation history and the current operation of the electronic apparatus 100 do not match, and may store the power consumption of the electronic apparatus 100 and the power consumption of another electronic apparatus 200 at the time when the power is cut off in the memory 120.

The processor 130 may identify the sum of the power consumption of the electronic apparatus 100 and the power consumption of another electronic apparatus 200 at the time when the power is cut off as the threshold power. In addition, when there are a plurality of power cut-off histories stored in the memory 120, the lowest value from the sum of the power consumption of the electronic apparatus 100 and the power consumption of another electronic apparatus 200 in each of the plurality of power cut-off histories can be identified as the threshold power.

Meanwhile, the electronic apparatus 100 may be a dryer and another electronic apparatus 200 may be a washing machine, and when the identified power consumption is equal to or greater than the threshold power, the processor 130 may control the communication interface 110 to transmit a control signal for changing at least one of the operations of another electronic apparatus 200 to another electronic apparatus 200. In general, the operation of the dryer is premised on the operation of the washing machine, so it is highly likely that only the dryer will operate in the end. Accordingly, by prioritizing the operation of the dryer as described above, the final operation end time of the dryer and the washing machine can be brought forward.

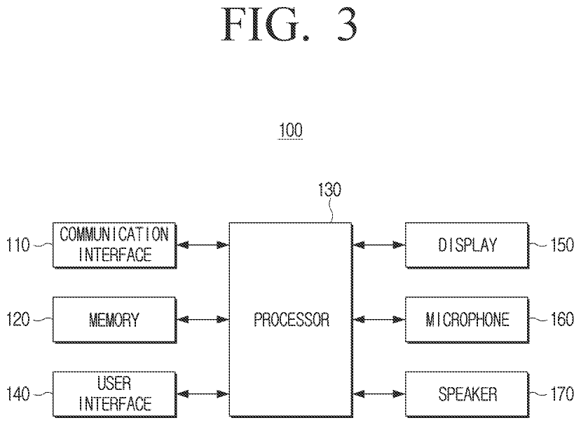

FIG. 3 is a block diagram illustrating detailed configuration of an electronic apparatus according to an embodiment of the disclosure.

Referring to FIG. 3, the electronic apparatus 100 may include the communication interface 110, the memory 120 and the processor 130. In addition, according to FIG. 3, the electronic apparatus 100 may further include a user interface 140, a display 150, a microphone 160, and a speaker 170. Among the components illustrated in FIG. 3, detailed descriptions of the components that overlap with those illustrated in FIG. 2 will be omitted.

The user interface 140 may be implemented as a button, a touch pad, a mouse, a keyboard, and the like, or may be implemented as a touch screen that can also perform a display function and a manipulation input function. The button may be a various type of buttons such as a mechanical button, a touch pad, a wheel, and the like. formed in any arbitrary area such as the side, the back, and the like.

The display 150 is configured to display an image, and may be implemented as various types of displays such as a Liquid Crystal Display (LCD), an Organic Light Emitting Diodes (OLED) display, a Plasma Display Panel (PDP), and the like. The display 150 may also include a driving circuit, a backlight unit, and the like, that can be implemented in the form of amorphous silicon (a-si) thin-film transistor (TFT), low temperature poly silicon (LTPS) TFT, organic TFT (OTFT), and the like. Meanwhile, the display 150 may be implemented as a touch screen combined with a touch sensor, a flexible display, a three dimensional (3D) display, and the like.

The processor 130 may control the display 150 to display at least one operation state of the electronic apparatus 100 or another electronic apparatus 200.

The microphone 160 is configured to receive sound and convert it into an audio signal. The microphone 160 is electrically connected to the processor 130, and may receive sound under the control of the processor 130.

For example, the microphone 160 may be integrally formed in the direction of the top, side, and the like, of the electronic apparatus 100. Alternatively, the microphone 160 may be formed on a remote controller, and the like, that is separate from the electronic apparatus 100. In this case, the remote controller may receive sound through the microphone 160, and provide the received sound to the electronic apparatus 100.

The microphone 160 may include various components such as a microphone that collects analog sound, an amplification circuit that amplifies the collected sound, an analog-to-digital (A/D) conversion circuit that samples the amplified sound and converts it into a digital signal, a filter circuit that removes noise components from the converted digital signal, and the like.

Meanwhile, the microphone 160 may be implemented in the form of a sound sensor or in any form that can collect sound.

The processor 130 may receive a user command through the microphone 160.

The speaker 170 is configured to output not only various audio data processed by the processer 130 but also various notification sounds, voice messages, and the like.

The processor 130 may control the speaker 170 to output sound guiding an operation state of at least one of the electronic apparatus 100 or another electronic apparatus 200.

As described above, the electronic apparatus 100 may prevent a situation in which power is cut off by controlling at least one of an operation of the electronic apparatus 100 or an operation of another electronic apparatus 200 so that the power consumption of the electronic apparatus 100 and another electronic apparatus 200 becomes less than the threshold power based on the operation information of another electronic apparatus 200.

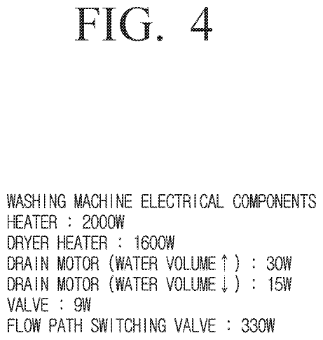

Hereinafter, the operation of the electronic apparatus 100 will be described in greater detail through FIGS. 4 to 12. In FIGS. 4 to 12, individual embodiments will be described for convenience of explanation. However, the individual embodiments of FIGS. 4 to 12 may be implemented in any form of combinations.

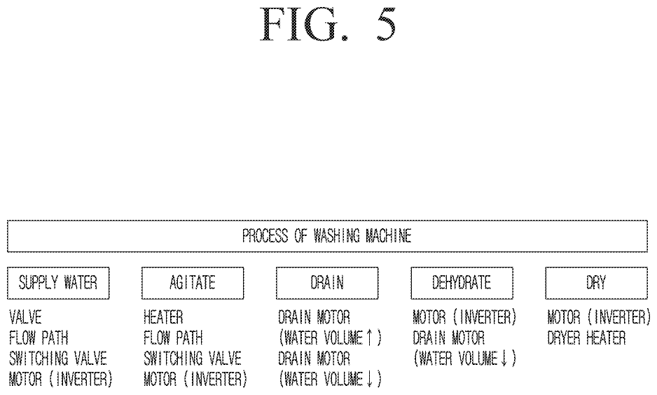

FIGS. 4 and 5 are views provided to explain power consumed for each operation according to various embodiments of the disclosure.

FIG. 4 illustrates the electrical components and power consumption of a washing machine or a dryer. The electrical components may be a load controlled by the washing machine or the dryer. The power consumption may be the amount of power usage predicted when the electrical components are operated for a certain period of time.

Referring to FIG. 5, the memory 120 may store a power consumption for each detailed operation of the electronic apparatus 100. In addition, the memory 120 may store a power consumption for each detailed operation of another electronic apparatus 200.

For example, as illustrated in FIG. 4, in case a heater operates, a power consumption of 2000 W occurs, in case a dryer heater operates, a power consumption of 1600 W occurs, in case a drain motor operates when the water volume is high, a power consumption of 30 W occurs, in case a drain motor operates when the water volume is low, a power consumption of 15 W may occur, in case a valve operates, a power consumption of 9 W may occur, and in case a flow path switching valve operates, a power consumption of 330 W may occur, and the memory 120 may store a power consumption for each detailed operation as described above.

Referring to FIG. 5, the order of the washing process of a washing machine. For example, the washing machine washes laundry in the following order: supplying water, agitating, draining, dehydrating, and drying. The water-supplying step may include electrical components such as a valve, a flow path switching valve and a motor (an inverter). The agitating step may include electrical components such as a heater, a flow path switching valve, a motor (an inverter). The draining step may include electrical components such as a drain motor when the water volume is high and a drain motor when the water volume is low. The dehydrating step may include electrical components such as a motor (an inverter) and a drain motor when the water volume is low. The drying step may include electrical components such as a motor (an inverter) and a dry heater.

The washing machine may identify the power consumption and expected completion time of each step based on the electrical components of each step, and transmit the identified information to the dryer. The dryer may identify the power consumption and expected completion time of each step based on the electrical components of each step included in the drying process. The dryer may identify a maximum power consumption of each of a plurality of time sections based on the information received from the washing machine and the power consumption and expected completion time of each step included in the drying process. Since the expected completion time of each step of the washing machine and the expected completion time of each step of the dryer may be different from each other and thus, the dryer may identify a maximum power consumption of each of the plurality of time sections which are divided in greater detail than the plurality of time sections included in the washing process and the plurality of time sections included in the drying process. For example, when the washing process includes the steps of 0˜10 minutes, 10˜20 minutes, and 20˜30 minutes and the drying process includes the steps of 0˜15 minutes and 15˜30 minutes, the dryer may identify a maximum power consumption of each time section of 0˜10 minutes, 10˜15 minutes, 15˜20 minutes, and 20˜30 minutes.

However, the disclosure is not limited thereto, and the dryer may store information regarding a power consumption of the washing process. In this case, the washing machine may only provide information regarding each step included in the washing process and the expected completion time of each step.

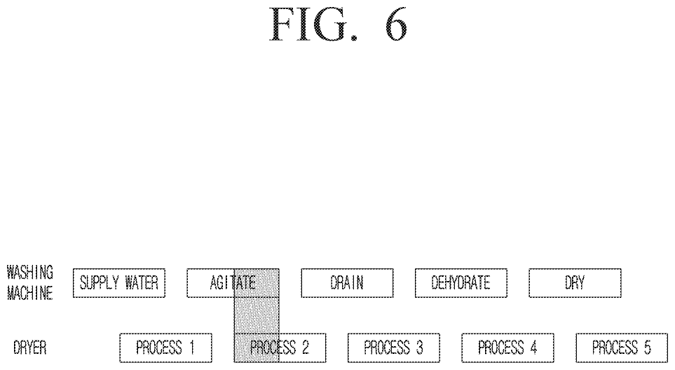

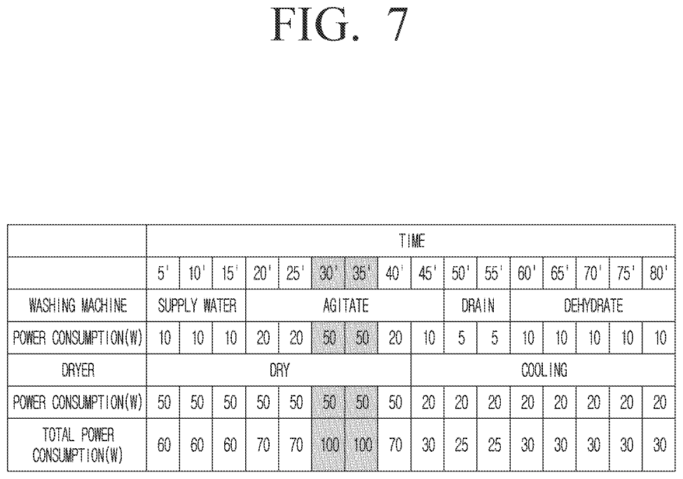

FIGS. 6 and 7 are views provided to explain a case where a power consumption is equal to or greater than threshold power according to various embodiments of the disclosure.

Referring to FIG. 6, when displaying the washing process of the washing machine and the drying process of the dryer in steps, a power consumption may be large in the agitating step of the washing machine and the second step of the process of the dryer.

FIG. 7 illustrates a more detailed example. For convenience of description, FIG. 7 illustrates that the electronic apparatus 100 is a dryer and another electronic apparatus 200 is a washing machine, and the processor 130 identifies a power consumption at 5-minute intervals.

Referring to FIG. 7, the processor 130 may identify the total power consumption of the dryer and the washing machine at 5-minute intervals. The processor 130 may identify that the total power consumption is the highest in the agitating step of the washing machine and the drying step of the dryer. In the agitating step of FIG. 7, the 25˜35 minute section is a state in which the power consumption of the washing machine has increased due to the operation of the heater motor for adjusting water temperature, and the processor 130 may take measures to prevent power cut-off by comparing the total power consumption and the threshold power of the corresponding section.

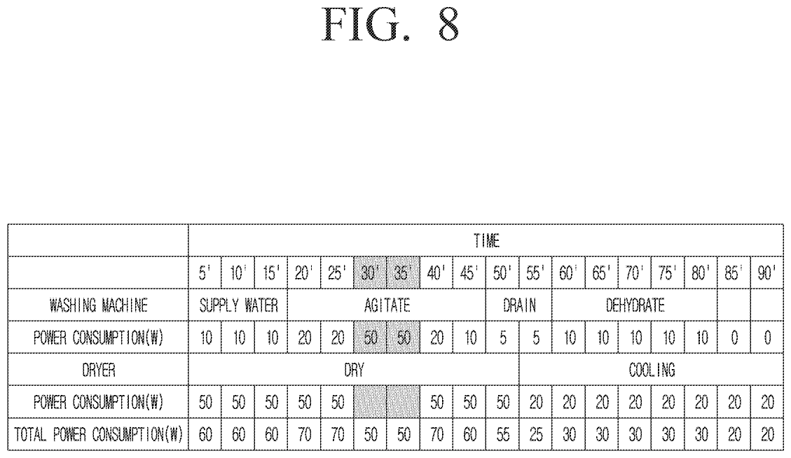

FIGS. 8, 9, and 10 are views provided to explain an operation method in a case where a power consumption is equal to or greater than threshold power according to various embodiments of the disclosure. For convenience of explanation, FIGS. 8 to 10 assumes that only the power consumption of the 25˜35 minute section is equal to or greater than the threshold power.

When the power consumption is equal to or greater the threshold power, the processor 130 may perform at least one of delaying at least one of an operation of the electronic apparatus 100 or an operation of another electronic apparatus 200, changing an order of a subordinate operation or changing control output.

Referring to FIG. 8, when the power consumption is equal to or greater than the threshold power, the processor 130 may stop the operation of the 25˜35 section among the drying steps of the dryer, and restart the drying operation from 35 minutes. In other words, the processor 130 may delay the operation of the dryer from 25 minutes for 10 minutes. In this case, the power consumption of the 25˜35 minute section is lowered from 100 to 50 and the possibility of power cut-off may decrease.

Although FIG. 8 describes that the operation of the electronic apparatus 100 is delayed, the disclosure is not limited thereto. For example, the processor 130 delays the operation of the electronic apparatus 100 and then, controls the electronic apparatus 100 to perform an additional operation. In the above-described example, the processor 130 may delay the operation of the dryer from 25 minutes for 10 minutes and then, add the drying operation for 5 minutes. This may be to compensate for the lowering of the internal temperature as the drying operation of the dryer is stopped.

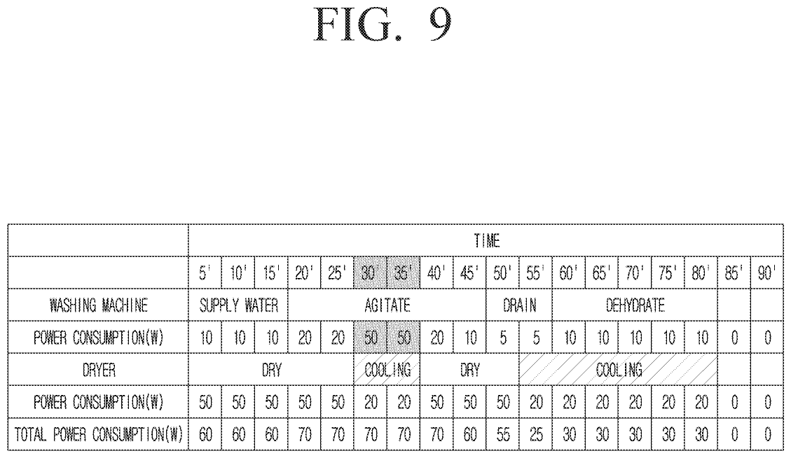

Referring to FIG. 9, when the power consumption is equal to or greater than the threshold power, the processor 130 may change the operation of the 25˜35 minute section among the drying steps of the dryer to a cooling operation, and change the operation of the 40˜50 section among the cooling steps of the dryer to a drying operation. In other words, the processor 130 may change the order of part of the cooling operation and the order of part of the drying operation, and compared to FIG. 8, there is an advantage that the end point of time of the entire process does not change.

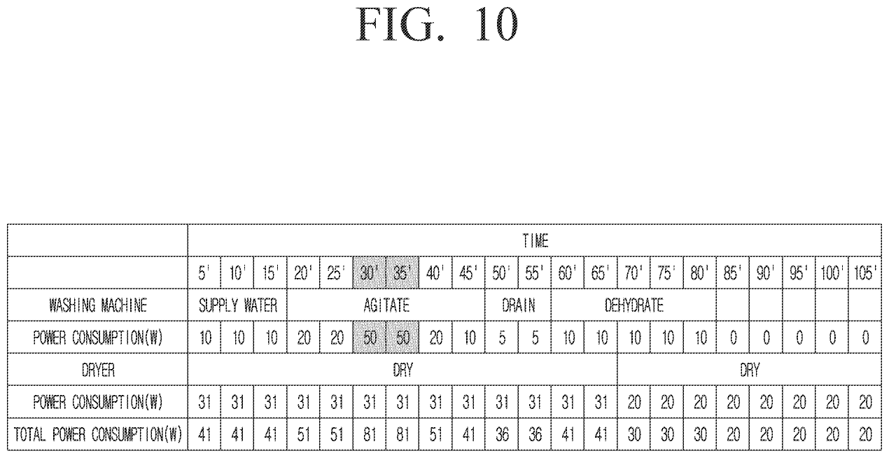

Referring to FIG. 10, when the power consumption is equal to or greater than the threshold power, the processor 130 may change the control output of the drying step of the dryer from 50 W to 31 W, and the time of the drying step from 40 minutes to 65 minutes. However, the disclosure is not limited thereto, and the processor 130 may change control output of at least one of the operation of the electronic apparatus 100 or the operation of another electronic apparatus 200 based on the time section where the power consumption is equal to or greater than the threshold power. For example, when the power consumption is equal to or greater than the threshold power, the processor 130 changes the control output of the 25˜35 minute section among the drying steps of the dryer from 50 W to 33 W, and changes the time of the drying step of the corresponding section from 10 minutes to 15 minutes.

Meanwhile, FIGS. 8 to 10 illustrate that the washing machine and the dryer operate simultaneously, but the disclosure is not limited thereto. For example, when the electronic apparatus 100 starts operating before another electronic apparatus 200, the processor 130 requests operation information from another electronic apparatus 200, and receives information that no operation is performed from another electronic apparatus. In this case, since another electronic apparatus 200 does not operate, the processor 130 may not identify the power consumption. Subsequently, when another electronic apparatus 200 starts operating based on a user command, another electronic apparatus 200 may transmit the operation information of another electronic apparatus 200 to the electronic apparatus 100. The processor 130 may identify the power consumption of each of the plurality of time sections based on the current operation information of the electronic apparatus 100 and the received operation information of another electronic apparatus 200.

Alternatively, when another electronic apparatus 200 starts operating before the electronic apparatus 100, another electronic apparatus 200 may transmit the operation information of another electronic apparatus 200 to the electronic apparatus 100, but the processor 130 may not identify the power consumption since the electronic apparatus 100 does not operate. However, the processor 130 may store the received operation information of another electronic apparatus 200 in the memory 120. Subsequently, when the electronic apparatus 100 starts operating based on a user command, the processor 130 may identify the power consumption of each of the plurality of time sections based on the operation information of the electronic apparatus 100 and the received operation information of another electronic apparatus 200. However, the disclosure is not limited thereto, and the processor 130 may not store the received operation information of another electronic apparatus 200 in the memory 120. In this case, when a user command for performing the operation of the electronic apparatus 100 is received, the processor 130 may request operation information from another electronic apparatus 200, and may identify the power consumption of each of the plurality of time sections based on the operation information received from another electronic apparatus 200 and the operation information of the electronic apparatus 100.

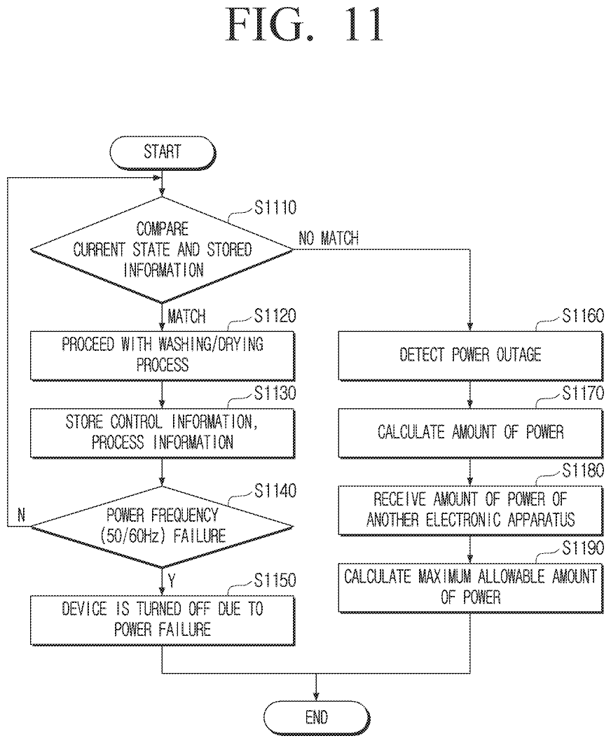

FIG. 11 is a flowchart provided to explain a method of calculating threshold power according to an embodiment of the disclosure.

Referring to FIG. 11, the processor 130 may compare the current state and stored information at operation S1110. For example, the processor 130 may periodically store the current operation in the memory 120, and may compare whether the final operation stored in the memory 120 matches the current operation at predetermined time intervals.

When the current state and the stored information match, the processor 130 may proceed with the washing/drying process at operation S1120, and store control information and process information in the memory 120 (at operation S1130).

Subsequently, when a power frequency failure does not occur at operation S1140—N, the operation of S1110 may be restarted, and when a power frequency failure occurs at operation S1140—Y, the electronic apparatus 100 may be turned off due to the power failure at operation S1150. The power frequency failure may occur due to an external factor, or may occur as the power consumption of the electronic apparatus 100 or another electronic apparatus 200 is equal to or greater than the threshold power.

When the current state and the stored information do not match, the processor 130 may detect that a power outage has occurred at operation S1160. For example, when the final operation stored in the memory 120 is a drying operation or the electronic apparatus 100 does not perform any operation, the processor 130 may identify that power has not supplied since information regarding the termination of the drying operation is not stored in the memory 120.

When it is identified that power has not been supplied, the processor 130 may identify the power consumption at the time of the final operation S1170, and may receive the power consumption of another electronic apparatus 200 (at operation S1180). For example, when the final operation of the electronic apparatus 100 stored in the memory 120 is a drying operation, the processor 130 may identify the power consumption of the drying operation, and may receive the power consumption of the agitating operation at the time of the final operation from another electronic apparatus 200. However, the disclosure is not limited thereto, and the final operation of the electronic apparatus 100 and the final operation of another electronic apparatus 200 may be stored in the memory 120, and the processor 130 may identify the power consumption of the electronic apparatus 100 and another electronic apparatus 200 at the time of power cut-off based on the information stored in the memory 120.

The processor 130 may calculate maximum allowable power based on the power consumption of the electronic apparatus 100 and the power consumption of another electronic apparatus 200 at operation S1190, and may use the maximum allowable power as the threshold power.

The process of FIG. 11 may be repeated multiple times in the process of using the electronic apparatus 100. In other words, the power cut-off history may be stored in the memory 120 multiple times. In this case, the processor 130 may identify the lowest value from the sum of the power consumption of the electronic apparatus 100 and the power consumption of another electronic apparatus 200 in each of the plurality of power cut-off histories as the threshold power.

Meanwhile, although FIG. 11 describes that the maximum allowable power is used as the threshold power, the disclosure is not limited thereto. For example, when the maximum allowable power is calculated, the processor 130 may identify a value corresponding to a predetermined ratio of the maximum allowable power as the threshold power. For instance, the processor 30 may identify 900 W corresponding to 90%, a predetermined ratio of the maximum allowable power of 1000 W as the threshold power. As such, the possibility of power cut-off may be lowered further by providing a margin for the power consumption.

In addition, through the operation of FIG. 11, there is an advantage that it is possible to perform an operation adaptive to each household.

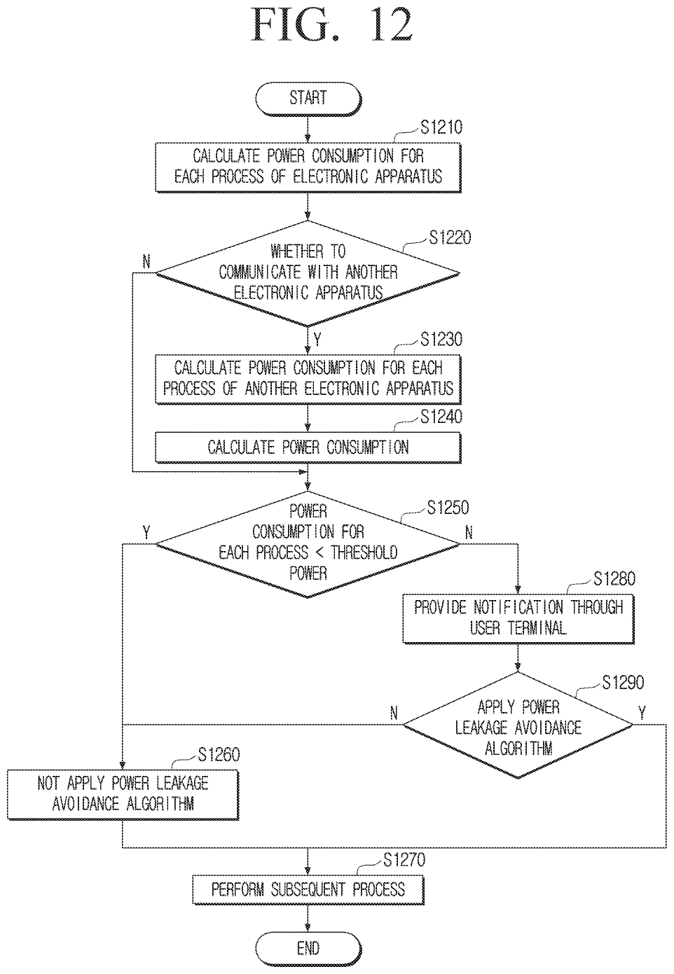

FIG. 12 is a flowchart provided to explain a power cut-off avoidance operation according to an embodiment of the disclosure.

Referring to FIG. 12, the processor 130 may calculate a power consumption for each process of the electronic apparatus 100 and another electronic apparatus 200 at operation S1210.

The processor 130 may identify whether there is communication with another electronic apparatus at operation S1220, and when the communication is possible, calculate the power consumption for each process of another electronic apparatus 200 at operation S1230 and calculate the power consumption for each consumption process of the electronic apparatus 100 at operation S1240.

The processor 130 may compare the power consumption for each process with the threshold power at operation S1250, and when the power consumption is less than the threshold power, may not apply a power leakage avoidance algorithm at operation S1260 and perform a subsequent process at operation S1270.

Alternatively, when the power consumption is equal to or greater than the threshold power, the processor 130 may provide a notification through a user terminal at operation S1280, and may identify whether to apply the power leakage avoidance algorithm according to a user command at operation S1290.

When a user command not to apply the power leakage avoidance algorithm is received, the processor 130 may not apply the power leakage avoidance algorithm at operation S1260 and perform a subsequent processor at operation S1270. Alternatively, when a user command to apply the power leakage avoidance algorithm is received, the processor 130 may apply the power leakage avoidance algorithm and then, perform a subsequent process at operation S1270.

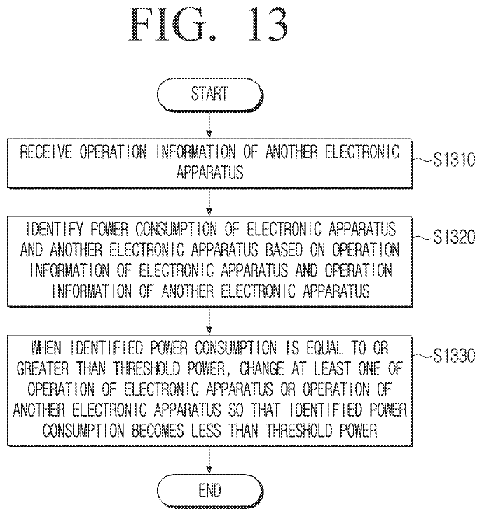

FIG. 13 is a flowchart provided to explain a controlling method of an electronic apparatus according to an embodiment of the disclosure.

Referring to FIG. 13, the controlling method includes receiving operation information of another electronic apparatus at operation S1310. In addition, the controlling method includes identifying a power consumption of the electronic apparatus and another electronic apparatus based on the operation information of the electronic apparatus and the operation information of another electronic apparatus at operation S1320. The controlling method includes, when the identified power consumption is equal to or greater than threshold power, changing at least one of the operations of the electronic apparatus or the operation of another electronic apparatus so that the identified power consumption is less than the threshold power at operation S1330.

In addition, the step of changing at operation S1330 may include, when the identified power consumption is equal to or greater than the threshold power, performing at least one of delaying at least one of an operation of the electronic apparatus or an operation of another electronic apparatus, changing an order of a subordinate operation or changing control output.

The step of identifying at operation S1320 may include identifying a plurality of power consumptions corresponding to each of a plurality of time sections based on operation information of the electronic apparatus and the operation information of another electronic apparatus, and the step of changing at operation S1330 may include, when a power consumption equal to or greater than the threshold power is identified from among the plurality of power consumptions, changing at least one of the operation of the electronic apparatus or the operation of another electronic apparatus of a time section corresponding to the identified power consumption.

In addition, the controlling method may further include, when a control command for changing the operation of the electronic apparatus is received, reidentifying the power consumption of the electronic apparatus and another electronic apparatus based on the operation information of the electronic apparatus and the operation information of another electronic apparatus corresponding to the control command.

Further, the step of changing at operation S1320 may include, when the identified power consumption is equal to or greater than the threshold power, transmitting a message indicating that there is a possibility of power cut-off to a user terminal, and when a user command is received from the user terminal, changing at least one of the operations of the electronic apparatus or the operation of another electronic apparatus based on the user command.

In addition, the controlling method may further include storing an operation history of the electronic apparatus and another electronic apparatus at predetermined time intervals, when power is resupplied after the operation is stopped as the power is cut off during the operation of the electronic apparatus, identifying that the power has been cut off since the operation history does not match the current operation of the electronic apparatus, and storing the power consumption of the electronic apparatus and the power consumption of another electronic apparatus at a time when the power is cut off.

Further, the controlling method may further include identifying the sum of the power consumption of the electronic apparatus and the power consumption of another electronic apparatus at a time when the power is cut off as the threshold power.

In addition, the step of identifying the threshold power may include, when there is a plurality of power cut-off histories, identifying the lowest value from the sum of the power consumption of the electronic apparatus and the power consumption of another electronic apparatus in each of the plurality of power cut-off histories as the threshold power.

Further, the electronic apparatus and the other electronic apparatus may be supplied with power from the same power source.

In addition, the electronic apparatus may be a dryer and another electronic apparatus may be a washing machine. The step of changing at operation S1330 may include, when the identified power consumption is equal to or greater than the threshold power, transmitting a control signal for changing at least one of the operations of another electronic apparatus to another electronic apparatus.

According to the above-described various embodiments, the electronic apparatus may prevent a situation in which power is cut off by controlling at least one of an operation of the electronic apparatus or an operation of another electronic apparatus so that the power consumption of the electronic apparatus and another electronic apparatus becomes less than the threshold power based on the operation information of another electronic apparatus.

Meanwhile, according to an embodiment, the above-described various embodiments may be implemented as software including instructions stored in machine-readable storage media, which can be read by machines (e.g.: computers). The machines refer to devices that call instructions stored in a storage medium, and can operate according to the called instructions, and the devices may include an electronic device according to the aforementioned embodiments (e.g.: an electronic apparatus (A)). In case an instruction is executed by a processor, the processor may perform a function corresponding to the instruction by itself, or by using other components under its control. An instruction may include a code that is generated or executed by a compiler or an interpreter. The machine-readable storage medium may be provided in a form of a non-transitory storage medium. The term “non-transitory” means that the storage medium is tangible without including a signal, and does not distinguish whether data are semi-permanently or temporarily stored in the storage medium.

In addition, according to an embodiment, the above-described methods according to the various embodiments may be included and provided in a computer program product. The computer program product may be traded as a product between a seller and a purchaser. The computer program product may be distributed in a form of a storage medium (e.g., compact disc read only memory (CD-ROM)) that may be read by the machine or online through an application store (e.g., PlayStore™). In case of the online distribution, at least a portion of the computer program product may be at least temporarily stored in a storage medium such as memory of a server of a manufacturer, a server of an application store, or a relay server or be temporarily generated.

In addition, according to an embodiment, the above-described various embodiments are may be implemented in a recording medium that can be read by a computer or a similar device using software, hardware, or a combination thereof. In some cases, embodiments described herein may be implemented by a processor itself. According to software implementation, embodiments such as procedures and functions described in this specification may be implemented as separate software. Each piece of software may perform one or more functions and operations described herein.

Meanwhile, computer instructions for performing processing operations of devices according to the above-described various embodiments may be stored in a non-transitory computer-readable medium. When being executed by a processor of a specific device, the computer instructions stored in such a non-transitory computer-readable medium allows the specific device to perform processing operations in the device according to the above-described various embodiments. The non-transitory computer-readable medium refers to a medium that stores data semi-permanently and can be read by a device, rather than a medium that stores data for a short period of time, such as registers, caches, and memories. Specific examples of the non-transitory computer-readable medium may include CD, digital versatile disc (DVD), hard disk, Blu-ray disc, USB, memory card, ROM, and the like.

The components (e.g., modules or programs) according to various embodiments described above may include a single entity or a plurality of entities, and some of the corresponding sub-components described above may be omitted or other sub-components may be further included in the various embodiments. Alternatively or additionally, some components (e.g., modules or programs) may be integrated into one entity and perform the same or similar functions performed by each corresponding component prior to integration. Operations performed by the modules, the programs, or the other components according to the diverse embodiments may be executed in a sequential manner, a parallel manner, an iterative manner, or a heuristic manner, at least some of the operations may be performed in a different order or be omitted, or other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic apparatus comprising:
a communication interface;
memory storing one or more computer programs; and
one or more processors communicatively connected to the communication interface and the memory,
wherein the one or more computer programs include computer-executable instructions that, when executed by the one or more processors, cause the electronic apparatus to:
receive operation information of another electronic apparatus through the communication interface,
identify a power consumption of the electronic apparatus and the other electronic apparatus based on operation information of the electronic apparatus and the operation information of the other electronic apparatus, and
based on the identified power consumption being equal to or greater than threshold power, change at least one of an operation of the electronic apparatus or an operation of the other electronic apparatus so that the identified power consumption is less than the threshold power.

2. The electronic apparatus as claimed in claim 1, wherein the one or more computer programs further include computer-executable instructions that, when executed by the one or more processors, cause the electronic apparatus to, based on the identified power consumption being equal to or greater than the threshold power, perform at least one of delaying at least one of an operation of the electronic apparatus or an operation of the other electronic apparatus, changing an order of a subordinate operation or changing control output.

3. The electronic apparatus as claimed in claim 1, wherein the one or more computer programs further include computer-executable instructions that, when executed by the one or more processors, cause the electronic apparatus to:
identify a plurality of power consumptions corresponding to each of a plurality of time periods based on the operation information of the electronic apparatus and the operation information of the other electronic apparatus, and
based on identifying the power consumption to be equal to or greater than the threshold power, change at least one of an operation of the electronic apparatus or an operation of the other electronic apparatus of a time period corresponding to the identified power consumption.

4. The electronic apparatus as claimed in claim 1, further comprising:
a user interface,
wherein the one or more computer programs further include computer-executable instructions that, when executed by the one or more processors, cause the electronic apparatus to, based on a control command for changing an operation of the electronic apparatus being received through the user interface, re-identify a power consumption of the electronic apparatus and the other electronic apparatus based on the operation information of the electronic apparatus and the operation information of the other electronic apparatus corresponding to the control command.

5. The electronic apparatus as claimed in claim 1, wherein the one or more computer programs further include computer-executable instructions that, when executed by the one or more processors, cause the electronic apparatus to:
based on the identified power consumption being equal to or greater than the threshold power, control the communication interface to transmit a message indicating a possible power cut-off to a user terminal, and
based on a user command being received from the user terminal through the communication interface, change at least one of an operation of the electronic apparatus or an operation of the other electronic apparatus based on the user command.

6. The electronic apparatus as claimed in claim 1, wherein the one or more computer programs further include computer-executable instructions that, when executed by the one or more processors, cause the electronic apparatus to:
store an operation history of the electronic apparatus and the other electronic apparatus in the memory at predetermined time interval,
based on a power being supplied again after the power is cut-off while the electronic apparatus is in operation and thus, the operation is stopped, identify the power cut-off as it is identified that the operation history and a current operation of the electronic apparatus do not match, and
store a power consumption of the electronic apparatus and a power consumption of the other electronic apparatus at a time of the power cut-off in the memory.

7. The electronic apparatus as claimed in claim 6, wherein the one or more computer programs further include computer-executable instructions that, when executed by the one or more processors, cause the electronic apparatus to identify a sum of the power consumption of the electronic apparatus and the power consumption of the other electronic apparatus at the time of the power cut-off as the threshold power.

8. The electronic apparatus as claimed in claim 7, wherein the one or more computer programs further include computer-executable instructions that, when executed by the one or more processors, cause the electronic apparatus to, based on a plurality of power cut-off histories being stored in the memory, identify a lowest value from the sum of the power consumption of the electronic apparatus and the power consumption of the other electronic apparatus in each of the plurality of power cut-off histories as the threshold power.

9. The electronic apparatus as claimed in claim 1, wherein the electronic apparatus and the other electronic apparatus receive power from a same power source.

10. The electronic apparatus as claimed in claim 1,
wherein the electronic apparatus is a dryer,
wherein the other electronic apparatus is a washing machine, and
wherein the one or more computer programs further include computer-executable instructions that, when executed by the one or more processors, cause the electronic apparatus to, based on the identified power consumption being equal to or greater than the threshold power, control the communication interface to transmit a control signal for changing at least one of operations of the other electronic apparatus to the other electronic apparatus.

11. A method of controlling an electronic apparatus, the method comprising:
receiving, by the electronic apparatus, operation information of another electronic apparatus;
identifying, by the electronic apparatus, a power consumption of the electronic apparatus and the other electronic apparatus based on operation information of the electronic apparatus and the operation information of the other electronic apparatus; and
based on the identified power consumption being equal to or greater than threshold power, changing, by the electronic apparatus, at least one of an operation of the electronic apparatus or an operation of the other electronic apparatus so that the identified power consumption is less than the threshold power.

12. The method as claimed in claim 11, wherein the changing of the at least one of an operation of the electronic apparatus or the operation of the other electronic apparatus comprises, based on the identified power consumption being equal to or greater than the threshold power, performing at least one of delaying at least one of an operation of the electronic apparatus or an operation of the other electronic apparatus, changing an order of a subordinate operation or changing control output.

13. The method as claimed in claim 11,
wherein the identifying of the power consumption of the electronic apparatus and the other electronic apparatus comprises identifying a plurality of power consumptions corresponding to each of a plurality of time periods based on the operation information of the electronic apparatus and the operation information of the other electronic apparatus, and
wherein the changing of the at least one of an operation of the electronic apparatus or the operation of the other electronic apparatus comprises, based on identifying the power consumption to be equal to or greater than the threshold power, changing at least one of an operation of the electronic apparatus or an operation of the other electronic apparatus of a time period corresponding to the identified power consumption.

14. The method as claimed in claim 11, further comprising:
based on a control command for changing an operation of the electronic apparatus being received, re-identifying a power consumption of the electronic apparatus and the other electronic apparatus based on the operation information of the electronic apparatus and the operation information of the other electronic apparatus corresponding to the control command.

15. The method as claimed in claim 11, wherein the changing comprises:
based on the identified power consumption being equal to or greater than the threshold power, transmitting a message indicating a possible power cut-off to a user terminal; and
based on a user command being received from the user terminal, changing at least one of an operation of the electronic apparatus or an operation of the other electronic apparatus based on the user command.

16. The method of claim 11, wherein the electronic apparatus is a dryer and the other electronic apparatus is a washing machine.

17. The method of claim 11, wherein, when the power consumption is less than the threshold power, avoid applying a power leakage avoidance algorithm and perform a subsequent process.

18. The method of claim 17, wherein, when the power consumption is greater than or equal to the threshold power:
providing a notification through a user; and
identifying whether to apply the power leakage avoidance algorithm according to a user command.

19. One or more non-transitory computer-readable storage media storing one or more computer programs including computer-executable instructions that, when executed by one or more processors of an electronic apparatus, cause the electronic apparatus to perform operations, the operations comprising:
receiving, by the electronic apparatus, operation information of another electronic apparatus;
identifying, by the electronic apparatus, a power consumption of the electronic apparatus and the other electronic apparatus based on operation information of the electronic apparatus and the operation information of the other electronic apparatus; and
based on the identified power consumption being equal to or greater than threshold power, changing, by the electronic apparatus, at least one of an operation of the electronic apparatus or an operation of the other electronic apparatus so that the identified power consumption is less than the threshold power.

20. The one or more non-transitory computer-readable storage media of claim 19, the operations further comprising:
based on the identified power consumption being equal to or greater than the threshold power, perform at least one of delaying at least one of an operation of the electronic apparatus or an operation of the other electronic apparatus, changing an order of a subordinate operation or changing control output.
